(19) United States
(12) Patent Application Publication
(10) Pub. No.: US 2025/0322887 A1
(43) Pub. Date: Oct. 16, 2025

(54) MEMORY DEVICE AND OPERATION METHODS THEREOF

(71) Applicant: YANGTZE MEMORY TECHNOLOGIES CO., LTD., Wuhan (CN)

(72) Inventors: Jing Wei, Wuhan (CN); Masao Kuriyama, Wuhan (CN); Lu Qiu, Wuhan (CN); Dong He, Wuhan (CN)

(21) Appl. No.: 18/669,264

(22) Filed: May 20, 2024

Related U.S. Application Data
(63) Continuation of application No. PCT/CN2024/087488, filed on Apr. 12, 2024.

(51) Int. Cl. G11C 16/26; G11C 16/04

(52) U.S. Cl. CPC G11C 16/26; G11C 16/0483

(57) ABSTRACT

In certain aspects, a memory device includes an array of memory cells, word lines respectively coupled to rows of the memory cells, and a peripheral circuit coupled to the array of memory cells through the word lines and configured to read a select row of the rows of the memory cells. The peripheral circuit includes a word line driver coupled to the select row through a select word line of the word lines and to an unselect row of the rows of the memory cells through an unselect word line of the word lines, and configured to apply a pass voltage to the unselect word line, and discharge the unselect word line from the pass voltage to a first recovery voltage that is greater than a supply voltage of the array of memory cells.

### CROSS-REFERENCE TO RELATED APPLICATIONS

This application is a continuation of International Application No. PCT/CN2024/087488, filed on Apr. 12, 2024, entitled “MEMORY DEVICE AND OPERATION METHODS THEREOF,” which is hereby incorporated by reference in its entirety.

### BACKGROUND

The present disclosure relates to memory devices and operation methods thereof.

Flash memory is a low-cost, high-density, non-volatile solid-state storage medium that can be electrically erased and reprogrammed. Flash memory includes NOR Flash memory and NAND Flash memory. Various operations can be performed by Flash memory, such as read, program (write), and erase. For NAND Flash memory, an erase operation can be performed at the block level, and a program operation or a read operation can be performed at the page level.

### SUMMARY

In one aspect, a memory device includes an array of memory cells, word lines respectively coupled to rows of the memory cells, and a peripheral circuit coupled to the array of memory cells through the word lines and configured to read or verify a select row of the rows of the memory cells. To read or verify the select row, the peripheral circuit is configured to apply a first voltage to an unselect word line coupled to an unselect row of the rows of the memory cells in a first phase of a first setup-sense stage, and apply a second voltage higher than the first voltage to the unselect word line in a second phase after the first phase of the first setup-sense stage.

In some implementations, the peripheral circuit is further configured to apply a first read voltage or a first verify voltage to a select word line coupled to the select row of the rows of the memory cells in the first setup-sense stage.

In some implementations, the peripheral circuit is further configured to sense a state of a memory cell in the select row in the second phase.

In some implementations, the peripheral circuit is further configured to apply the first voltage to the unselect word line in a pre-pulse stage before the first setup-sense stage, and apply the first voltage to the select word line in the pre-pulse stage.

In some implementations, the peripheral circuit is further configured to apply the second voltage to the unselect word line in a pre-pulse stage before the first setup-sense stage, and apply the second voltage to the select word line in the pre-pulse stage.

In some implementations, the peripheral circuit is further configured to discharge the unselect word line to a third voltage lower than the second voltage in a post-pulse stage after the first setup-sense stage.

In some implementations, the peripheral circuit is further configured to charge the select word line to the third voltage in the post-pulse stage.

In some implementations, the peripheral circuit is further configured to apply a second read voltage or a second verify voltage to the select word line in a second setup-sense stage, apply the first voltage to the unselect word line in a first phase of the second setup-sense stage, and apply the second voltage to the unselect word line in a second phase after the first phase of the second setup-sense stage.

In some implementations, the second voltage is higher than threshold voltages of the memory cells in the select row.

In some implementations, the unselect word line is not immediately adjacent to the select word line.

In some implementations, the peripheral circuit is further configured to apply a same voltage to another unselect word line coupled to another unselect row of the rows of the memory cells in the first phase and the second phase of the first setup-sense stage. The another unselect word line is immediately adjacent to the select word line.

In some implementations, the unselect word line includes a first unselect word line and a second unselect word line, the second unselect word line is farther away from the select word line than the first unselect word line, and the first voltage applied to the first unselect word line is different from the first voltage applied to the second unselect word line in the first setup-sense stage.

In another aspect, a method for operating a memory device is provided. The memory device includes an array of memory cells and word lines respectively coupled to rows of the memory cells. A first read voltage or a first verify voltage is applied to a select word line of the word lines in a first setup-sense stage, the select word line being coupled to a select row of the rows of the memory cells. A first voltage is applied to an unselect word line of the word lines in a first phase of the first setup-sense stage, the unselect word line being coupled to an unselect row of the rows of the memory cells. A second voltage higher than the first voltage is applied to the unselect word line in a second phase after the first phase of the first setup-sense stage.

In some implementations, a state of a memory cell in the select row is sensed in the second phase.

In some implementations, the first voltage is applied to the unselect word line in a pre-pulse stage before the first setup-sense stage, and the first voltage is applied to the select word line in the pre-pulse stage.

In some implementations, the second voltage is applied to the unselect word line in a pre-pulse stage before the first setup-sense stage, and the second voltage is applied to the select word line in the pre-pulse stage.

In some implementations, the unselect word line is discharged to a third voltage lower than the second voltage in a post-pulse stage after the first setup-sense stage.

In some implementations, the select word line is charged to the third voltage in the post-pulse stage.

In some implementations, a second read voltage or a second verify voltage is applied to the select word line in a second setup-sense stage, the first voltage is applied to the unselect word line in a first phase of the second setup-sense stage, and the second voltage is applied to the unselect word line in a second phase after the first phase of the second setup-sense stage.

In some implementations, the second voltage is higher than threshold voltages of the memory cells in the select row.

In some implementations, the unselect word line is not immediately adjacent to the select word line.

In some implementations, a same voltage is applied to another unselect word line in the first phase and the second phase of the first setup-sense stage. The another unselect word line is coupled to another unselect row of the rows of the memory cells and being immediately adjacent to the select word line.

In some implementations, the unselect word line includes a first unselect word line and a second unselect word line, the second unselect word line is farther away from the select word line than the first unselect word line, and the first voltage applied to the first unselect word line is different from the first voltage applied to the second unselect word line in the first setup-sense stage.

In still another aspect, a system includes a memory device configured to store data and a memory controller coupled to the memory device and configured to control the memory device. The memory device includes an array of memory cells, word lines respectively coupled to rows of the memory cells, and a peripheral circuit coupled to the array of memory cells through the word lines and configured to read or verify a select row of the rows of the memory cells. To read or verify the select row, the peripheral circuit is configured to apply a first voltage to an unselect word line coupled to an unselect row of the rows of the memory cells in a first phase of a first setup-sense stage, and apply a second voltage higher than the first voltage to the unselect word line in a second phase after the first phase of the first setup-sense stage.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic diagram of a memory device including peripheral circuits, according to some aspects of the present disclosure.

FIG. 2 illustrates a side view of a cross-section of a memory cell array including a NAND memory string, according to some aspects of the present disclosure.

FIG. 3 illustrates a block diagram of a memory device including a memory cell array and peripheral circuits, according to some aspects of the present disclosure.

FIG. 4 illustrates a schematic diagram of a three-dimensional (3D) NAND memory string, according to some aspects of the present disclosure.

FIG. 5 illustrates a timing diagram of a read operation.

FIGS. 6A and 6B illustrate a waveform of word line voltages applied to a select word line in a program operation, according to some aspects of the present disclosure.

FIG. 7 illustrates a timing diagram of a read operation or a verify operation, according to some aspects of the present disclosure.

FIG. 8 illustrates another timing diagram of a read operation or a verify operation, according to some aspects of the present disclosure.

FIGS. 9 and 10 illustrate a flowchart of a method for operating a memory device, according to some aspects of the present disclosure.

FIG. 11 illustrates a block diagram of a system having a memory device, according to some aspects of the present disclosure.

FIG. 12A illustrates a diagram of a memory card having a memory device, according to some aspects of the present disclosure.

FIG. 12B illustrates a diagram of a solid-state drive (SSD) having a memory device, according to some aspects of the present disclosure.

The present disclosure will be described with reference to the accompanying drawings.

### DETAILED DESCRIPTION

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

During read operations of memory devices, such as NAND Flash memory devices, a relatively high bias voltage (e.g., pass voltage Vpass) needs to be applied to unselect word lines to turn on the channels, which may cause the shift of the threshold voltages Vt of corresponding memory cells, in particular, threshold voltage at the lower states, if the read operations are repeatedly performed by the same memory cells without any erase operation. This issue is known as “read disturbance” that may cause errors when reading data from those memory cells. Read disturbance can also be caused by the verify process of program operations (referred to herein as “verify operation”), which is similar to the read operations.

To address one or more of the aforementioned issues, the present disclosure introduces a flexible bias voltage control scheme to unselect word lines in the read operations or verify process of program operations. Except for the time periods in which the state of a memory cell is sensed (e.g., known as the sense phase), in other time periods in the read/verify operations, the bias voltage applied to the unselect word line does not need to reach the target level, thereby allowing a reduced bias voltage to decrease the time of high pass voltage stress on the corresponding memory cells. The flexible unselect word line bias voltage control scheme disclosed herein can reduce the bias voltage applied to the unselected word lines, compared to the constant voltage level, during the pre-pulse stage, the setup phase of the setup-sense stage, and/or the post-pulse stage in various implementations, thereby addressing the read disturbance issue.

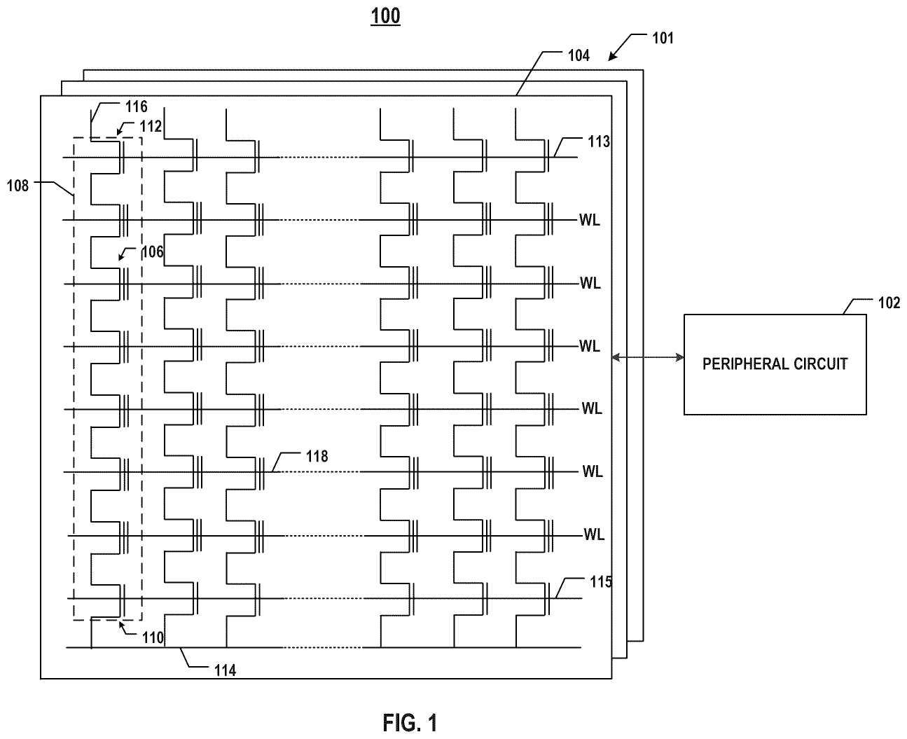

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge, which depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single level cell (SLC) that has two possible memory states (levels) and thus, can store one bit of data. For example, the first memory state “0” can correspond to a first range of threshold voltages, and the second memory state “1” can correspond to a second range of threshold voltages. In some implementations, each memory cell 106 is an xLC that is capable of storing more than a single bit of data in more than four memory states (levels). For example, the xLC may store two bits per cell (MLC), three bits per cell (TLC), or four bits per cell (QLC)). Each xLC can be programmed to assume a range of possible nominal storage values (i.e., corresponding to 2^{N} pieces of N-bits data). In one example, the MLC can be programmed to assume one of three possible programming levels from an erased state by writing one of three possible nominal storage values to the cell. A fourth nominal storage value can be used for the erased state.

As shown in FIG. 1, each NAND memory string 108 can also include a source select gate (SSG) transistor 110 at its source end and a drain select gate (DSG) transistor 112 at its drain end. SSG transistor 110 and DSG transistor 112 can be configured to activate select NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. The drain of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage to the gate of respective DSG transistor 112 through one or more DSG lines 113 and/or by applying a select voltage or a deselect voltage to the gate of respective SSG transistor 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a select block 104, source lines 114 coupled to select block 104 as well as unselect blocks 104 in the same plane as select block 104 can be biased with an erase voltage (Vers), such as a high positive bias voltage (e.g., 20 V or more). Memory cells 106 of adjacent NAND memory strings 108 can be coupled through word lines 118 that select which row of memory cells 106 is affected by read and program operations. In some implementations, each word line 118 is coupled to a plurality of memory cells 106. Each word line 118 can include a plurality of control gates (gate electrodes) at each memory cell 106 and a gate line coupling the control gates.

As shown in FIG. 1, memory cell array 101 can include an array of memory cells 106 in a plurality of rows and a plurality of columns in each block 104. One column of memory cells corresponds to one NAND memory string 108, according to some implementations. The plurality of rows of memory cells 106 can be respectively coupled to word lines 118, and the plurality of columns of memory cells 106 can be respectively coupled to bit lines 116. Peripheral circuit 102 can be coupled to memory cell array 101 through bit lines 116 and word lines 118.

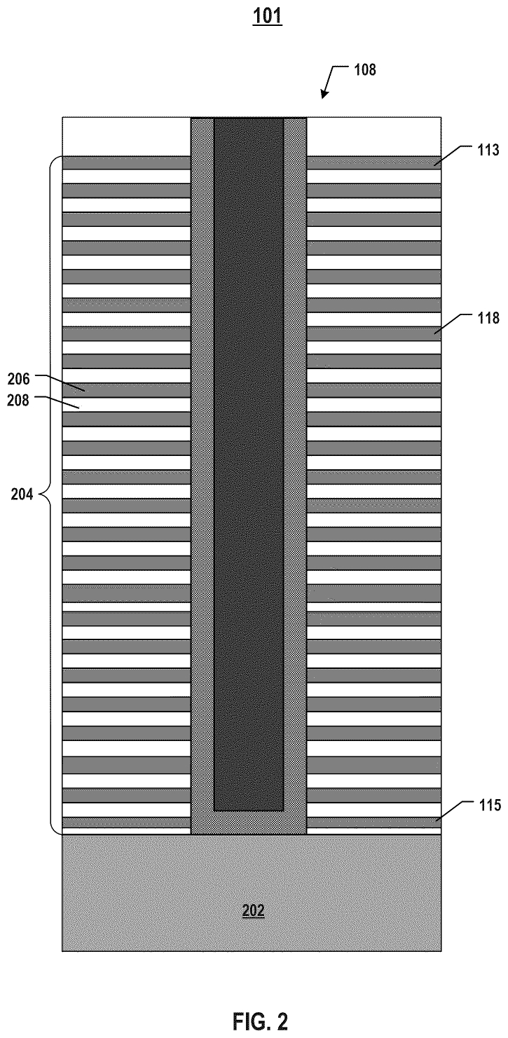

FIG. 2 illustrates a side view of a cross-section of memory cell array 101 including NAND memory string 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, the gates of DSG transistors 112, or the gates of SSG transistors 110, and can extend laterally as DSG line 113 at the top of memory stack 204, SSG line 115 at the bottom of memory stack 204, or word line 118 between DSG line 113 and SSG line 115.

As shown in FIG. 2, NAND memory string 108 includes a channel structure extending vertically through memory stack 204. In some implementations, the channel structure includes a channel hole filled with semiconductor material(s) (e.g., as a semiconductor channel) and dielectric material(s) (e.g., as a memory film). It is understood that although not shown in FIG. 2, additional components of memory cell array 101 can be formed including, but not limited to, gate line slits/source contacts, local contacts, interconnect layers, etc.

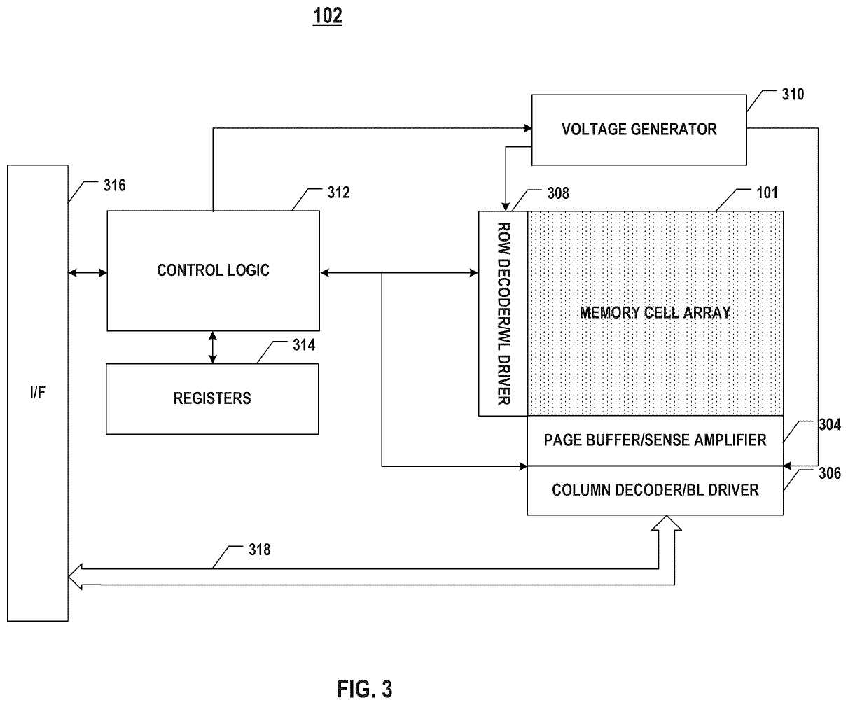

Referring back to FIG. 1, peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each select memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some exemplary peripheral circuits including a page buffer/sense amplifier 304, a column decoder/bit line driver 306, a row decoder/word line driver 308, a voltage generator 310, control logic 312, registers 314, an interface (I/F) 316, and a data bus 318. It is understood that in some examples, additional peripheral circuits not shown in FIG. 3 may be included as well.

Page buffer/sense amplifier 304 can be configured to sense (read) and program (write) data from and to memory cell array 101 according to the control signals from control logic 312. In one example, page buffer/sense amplifier 304 may store one or more pages of program data (write data, referred to herein as “data page”) to be programmed. In another example, page buffer/sense amplifier 304 may verify programmed select memory cells 106 in each program/verify cycle (loop) in a program operation to ensure that the data has been properly programmed into memory cells 106 coupled to select word lines 118. In still another example, page buffer/sense amplifier 304 may also sense the low power signals from bit line 116 that represents a data bit stored in memory cell 106 and amplify the small voltage swing to recognizable logic levels in a read operation.

Column decoder/bit line driver 306 can be configured to be controlled by control logic 312 and select one or more NAND memory strings 108 by applying bit line voltages generated from voltage generator 310. Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Voltage generator 310 can be configured to be controlled by control logic 312 and generate the word line voltages (e.g., read voltage, program voltage, channel pass voltage, local voltage, verify voltage, etc.), bit line voltages, and source line voltages to be supplied to memory cell array 101.

Control logic 312 can be coupled to each peripheral circuit described above and configured to control the operations of each peripheral circuit. Registers 314 can be coupled to control logic 312 and include status registers, command registers, and address registers for storing status information, command operation codes (OP codes), and command addresses for controlling the operations of each peripheral circuit. Interface 316 can be coupled to control logic 312 and act as a control buffer to buffer and relay control commands received from a memory controller (not shown) and/or a host (not shown) to control logic 312 and status information received from control logic 312 to the memory controller and/or the host. Interface 316 can also be coupled to column decoder/bit line driver 306 via data bus 318 and act as a data input/output (I/O) interface and a data buffer to buffer and relay the data to and from memory cell array 101.

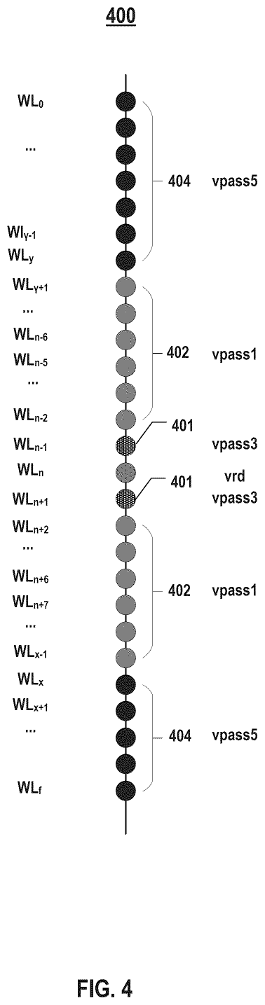

FIG. 4 illustrates a schematic diagram of a 3D NAND memory string 400, according to some aspects of the present disclosure. 3D NAND memory string 400 may be an example of NAND memory string 108 in FIG. 1. As shown in FIG. 4, from top to bottom, 3D NAND memory string 400 is coupled to a plurality of word lines WL₀ to WL_{f} (WLs, e.g., 118 in FIG. 1) in different rows. Read operations can be performed between memory cells in different rows from bottom to top (i.e., in the direction from WL_{f} to WL₀), or vice versa (e.g., in the direction from WL₀ to WL_{f}). As shown in FIG. 1, for example, a read operation may be performed on a select memory cell in 3D NAND memory string 400 that is coupled to WLₙ by applying a read voltage vrd to WLₙ. WLₙ to which the read voltage vrd is applied is referred to herein as “select word line.” Meanwhile, pass voltages vpass may be applied to the remaining word lines WL₀ to WLₙ₋₁ and WLₙ+1 to WL_{f} during the read operation. WL₀ to WLₙ₋₁ and WLₙ+1 to which the pass voltages vpass are applied are referred to herein as “unselect word lines.”

In some implementations, the unselect word lines are grouped based on their locations, e.g., the distances from the select word line WLₙ. For example, as shown in FIG. 4. The unselect word lines may be divided into three groups: (1) adjacent unselect word lines 401 WLₙ+1 and WLₙ₋₁ that are immediately adjacent to select word line WLₙ, (2) near unselect word lines 402 WLₙ+2 to WLₓ₋₁ and WLₙ₋₂ to WL_{y+1}, and (3) far unselect word lines 404 WLₓ to WL_{f} and WL_{y} to WL₀. In some implementations, each far unselect word line 404 is farther away from the select word line WLₙ than each near unselect word line 402. It is understood that the number of near unselect word lines 402 and the number of far unselect word lines 404 may vary in different examples. It is further understood that the unselect word lines may be grouped into more than three groups based on their locations, e.g., the distances from the select word line WLₙ, in other examples.

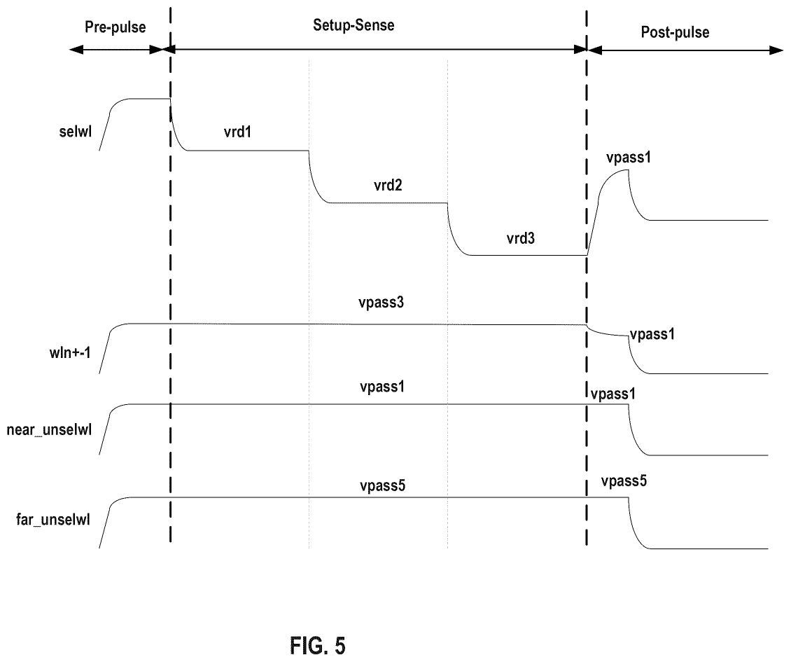

In some implementations, the pass voltages vpass applied to the unselect word lines in different groups are different. For example, as shown in FIG. 4, three pass voltages vpass1, vpass3, and vpass5 with different amplitudes may be applied to near unselect word lines 402, adjacent unselect word lines 401, and far unselect word lines 404, respectively. For example, FIG. 5 illustrates a timing diagram of a read operation with respect to 3D NAND memory string 400. In this example, vpass3 may be higher than vpass1, and vpass1 may be higher than vpass5. In other words, the amplitude of the pass voltage applied to adjacent unselect word lines 401 may be higher than the amplitude of the pass voltage applied to near unselect word lines 402, and the amplitude of the pass voltage applied to near unselect word lines 402 may be higher than the amplitude of the pass voltage applied to far unselect word lines 404.

As shown in FIG. 5, a read operation may include a pre-pulse stage (a.k.a. precharge stage), one or more setup-sense stages (e.g., three stages in FIG. 5) after the pre-pulse stage, and a post-pulse stage (a.k.a. recovery stage) after the setup-sense stage(s). In the pre-pulse stage, peripheral circuit 102 may be configured to control select 3D NAND memory strings (e.g., 3D NAND memory string 400) to be ready for reading. For example, word line driver 308 may be configured to charge the select DSG line and the SSG line to a select voltage that can turn on the DSG transistor and the SSG transistor of 3D NAND memory string 400, respectively (not shown in FIG. 5). Word line driver 308 may also be configured to charge the unselect word lines to their respective desired pass voltages vpass that can turn on the memory cells coupled to the unselect word lines (unselect memory cells). For example, at the end of the pre-pulse stage, word line driver 308 may apply a pass voltage vpass to each unselect word line that is higher than the threshold voltage of the respective unselect memory cell to turn on the respective unselect memory. That is, at the end of the pre-pulse stage, in 3D NAND memory string 400, DSG transistor, SSG transistor, and unselect memory cells may all be turned on by peripheral circuit 102.

As described above with respect to FIG. 4, in some implementations, unselect word lines in different groups may be charged to different pass voltages at the end of the pre-pulse stage. For example, as shown in FIG. 5, at the end of the pre-pulse stage, adjacent unselect word lines 401 wln+−1 may be charged to vpass3, near unselect word lines 402 near_unselwl may be charged to vpass1, and far unselect word lines 404 far_unselwl may be charged to vpass5. In one example, vpass3 may be higher than vpass1, and vpass1 may be higher than vpass5.

In each of the setup-sense stages, peripheral circuit 102 may be configured to keep turning on the DSG transistors, SSG transistors, and unselect memory cells in 3D NAND memory string 400, and apply a respective read voltage to the select memory cell in 3D NAND memory string 400. For example, word line driver 308 may be configured to apply, to the select word line selwl, the first read voltage vrd1 when reading the first level in the first setup-sense stage, the second read voltage vrd2 when reading the second level in the second setup-sense stage, and the third read voltage vrd3 when reading the third level in the third setup-sense stage. Word line driver 308 may be further configured to apply and keep a respective pass voltage vpass to each unselect word line (e.g., vpass3 to win+−1, vpass1 to near_unselwl, and vpass5 to far_unselwl) when reading the first, second, and third levels in the first, second, and third setup-sense stages.

In the post-pulse stage, peripheral circuit 102 may be configured to control 3D NAND memory string 400 to recover from reading and be ready for the next operation. For example, word line driver 308 may be configured to discharge the select DSG line and the SSG line from the select voltage to turn off the DSG transistor and the SSG transistor, respectively (not shown in FIG. 5). It is understood that in the post-pulse stage, the voltage on the select word line selwl may be first coupled to be the same voltage applied on adjacent unselect word lines 401 wln+−1 in the post-pulse stage (e.g., vpass1 in FIG. 5) and then discharged from the coupled voltage to the supply voltage. The supply voltage referred to herein may be, for example, 0 voltage. Word line driver 308 may also be configured to discharge or charge the select word line selwl from the last read voltage (e.g., vrd3 in FIG. 5) back to the supply voltage. Word line driver 308 may be further configured to discharge the unselect word lines from their respective pass voltages vpass back to the supply voltage. For example, as shown in FIG. 5, word line driver 308 may be configured to discharge adjacent unselect word line 401 wln+−1 from vpass3 to vpass1 (the same voltage applied to near unselect word line 402 near_unselwl) and then discharge adjacent unselect word line 401 wln+−1 from vpass1 to the supply voltage. Word line driver 308 may also be configured to keep near unselect word line 402 near_unselwl at vpass1 at the beginning of the post-pulse stage until the voltage on adjacent unselect word line 401 wln+−1 being discharged to vpass1 and then discharge near unselect word line 402 near_unselwl from vpass1 to the supply voltage. Word line driver 308 may be further configured to keep far unselect word line 404 far_unselwl at vpass5 at the beginning of the post-pulse stage until the voltage on adjacent unselect word line 401 wln+−1 being discharged to vpass1 and then discharge far unselect word line 404 far_unselwl from vpass5 to the supply voltage.

In the read operation described with respect to FIG. 5, the pass voltage vpass5 applied to far unselect word lines 404 far_unselwl may be lower than the pass voltage vpass3 applied to adjacent unselect word lines 401 wln+−1 and the pass voltage vpass1 applied to near unselect word lines 402 near_unselwl in order to reduce the pass voltage stress on the corresponding memory cells coupled to far unselect word lines 404. However, during the entire setup-sense stages, the end of the pre-pulse stage, and the beginning of the post-pulse stage, the bias voltage applied to each near unselect word line 402 and far unselect word line 404 is kept at a constant level (vpass1 or vpass5), which may not be necessary for read operations. Thus, further improvements to read operations are needed to further reduce read disturbance caused by high pass voltage stress on unselect memory cells.

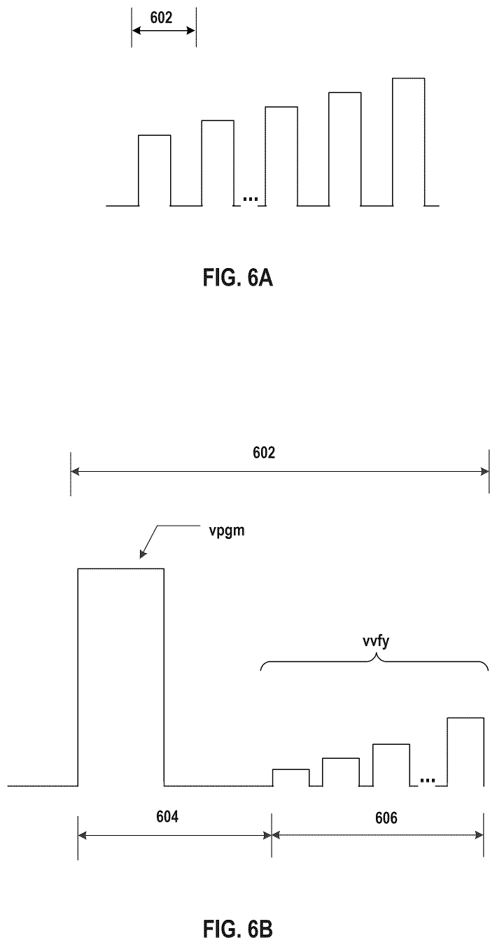

It is understood that although FIG. 5 describes a read operation, a verify process in a program operation (referred to herein as a verify operation) may have similar operating mechanisms and, therefore, encounter similar issues and needs as described above. FIGS. 6A and 6B illustrate a waveform of word line voltages applied to a select word line in a program operation, according to some aspects of the present disclosure.

As shown in FIGS. 6A and 6B, the program operation includes one or more loops 602, each of which includes a program cycle 604 and a verify cycle 606, according to some implementations. As shown in FIG. 6B, in each loop 602, word line driver 308 can be configured to apply a program voltage vpgm on the select word line in program cycle 604 and sequentially apply one or more verify voltages vvfy with incremental changes of voltage levels to verify the select memory cells coupled to the select word line in verify cycle 606. That is, in each loop 602, peripheral circuit 102 can perform a verify operation on select memory cells at one or more levels in verify cycle 606 after applying a program voltage in program cycle 604. The number of verify voltages applied in verify cycle 606 determines the number of setup-sense stages in verify cycle 606 and depends on the level being programmed by the specific loop 602, according to some implementations. As a result, at the end of the program operation, for example, each select memory cell may be programmed into one of the 2^{N} levels based on the corresponding N bits of data to be stored in the select memory cell, where N is a positive integer. It is understood that a verify operation may be performed in each verify cycle 606, similar to the read operation described above with respect to FIG. 5, except that one or more verify voltages vvfy, as opposed to one or more read voltages vrd, may be applied to the select word line selwl in respective setup-sense stages.

Consistent with the scope of the present disclosure, read and verify operations with a flexible bias voltage control scheme to unselect word lines implemented using memory devices disclosed herein (e.g., memory device 100) are described below in detail. The flexible unselect word line bias voltage control scheme disclosed herein can reduce the bias voltage applied to the unselected word lines (pass voltages), compared to the stable voltage level, during the pre-pulse stage, the setup phase of each setup-sense stage, and/or the post-pulse stage in various implementations, thereby further addressing the read disturbance issue.

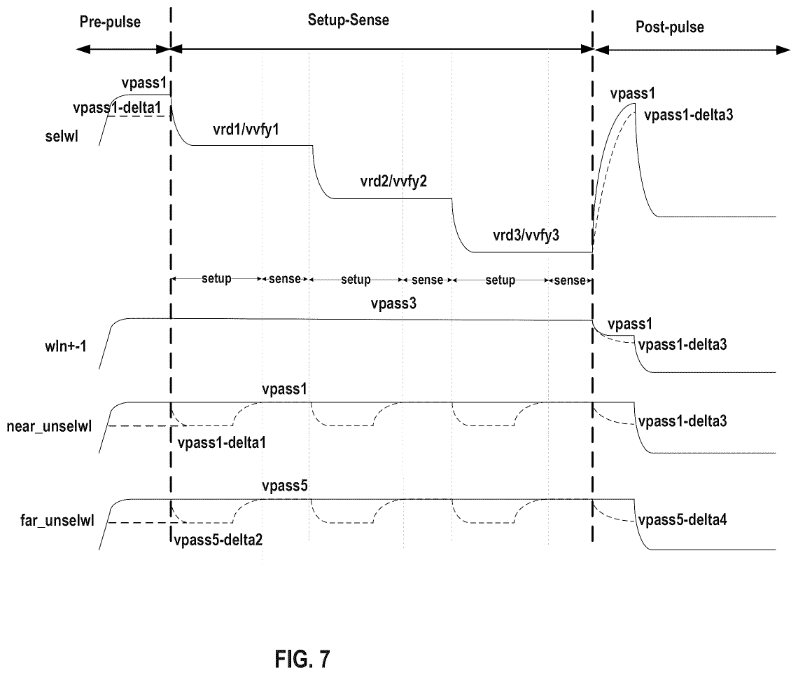

FIG. 7 illustrates a timing diagram of a read operation or a verify operation, according to some aspects of the present disclosure. As shown in FIG. 7, a read operation includes a pre-pulse stage (a.k.a. precharge stage), one or more setup-sense stages (e.g., three stages in FIG. 7) after the pre-pulse stage, and a post-pulse stage (a.k.a. recovery stage) after the setup-sense stage(s), according to some implementations. Each setup-sense stage can include a setup phase (first phase) and a sense phase (second phase) after the first phase. In some implementations, in each sense phase, peripheral circuit 102 is configured to sense the state (e.g., “0” or “1”) of a select memory cell (e.g., the memory cell coupled to the select word line selwl). For example, page buffer/sense amplifier 304 may sense the state of the select memory cell by comparing the voltage at the sensing node (SO) after a discharging time period in the sense phase with a threshold voltage Vtrip. In order to correctly sense the state of the select memory cell at the desired level in each sense phase, word line driver 308 can be configured to apply the corresponding read voltage vrd or verify voltage vvfy to the select word line selwl in the sense phase, for example, applying vrd1/vvrfy1 in the first sense phase for sensing at the first level, applying vrd2/vvrfy2 in the second sense phase for sensing at the second level, and applying vrd3/vvrfy3 in the third sense phase for sensing at the third level as shown in FIG. 7. In order to correctly sense the state of the select memory cell at the desired level in each sense phase, word line driver 308 can also be configured to apply a respective pass voltage to each unselect word line in the sense phase, for example, by applying vpass3 to win+−1, applying vpass1 to near_unselwl, and applying vpass5 to far_unselwl in each sense phase as shown in FIG. 7. As described above with respect to FIG. 5, vpass1, vpass3, and vpass5 may be different from one another. For example, vpass3 may be higher than vpass1, and vpass1 may be higher than vpass5.

In some implementations, in each setup phase, peripheral circuit 102 is configured to setup 3D NAND memory string 400 to be ready for sensing. Word line driver 308 can be configured to discharge the select word line selwl to the corresponding read voltage vrd or verify voltage vvfy in the setup phase, for example, discharging the select word line selwl from vpass1 or vpass1−delta1 (described below in detail) to vrd1/vvfy1 in the first setup phase, discharging the select word line selwl from vrd1/vvfy1 to vrd2/vvfy2 in the first setup phase, and discharging the select word line selwl from vrd2/vvfy2 to vrd3/vvfy3 in the first setup phase. That is, vrd1/vvfy1 may be higher than vrd2/vvfy2, and vrd2/vvfy2 may be higher than vrd3/vvfy3.

The flexible unselect word line bias voltage control scheme disclosed herein can reduce the bias voltage applied to the unselected word lines (pass voltages), compared to the stable voltage level, in the setup phase of each setup-sense stage. Since peripheral circuit 102 is configured to sense the select memory cell state only in the sense phase and merely set 3D NAND memory string 400 to be ready for sensing in the setup phase, at least some of the unselect word lines, such as the near unselect word lines near_unselwl and far unselect word lines far_unselwl, do not have to be kept at the desired voltage levels for sensing (e.g., vpass1 or vpass5) in the setup phase of each setup-sense stage, thereby allowing a reduced bias voltage to decrease the time of high pass voltage stress on the corresponding memory cells.

In some implementations, in each setup phase, word line driver 308 is configured to apply a bias voltage (first voltage) that is lower than the respective pass voltage (second voltage) to an unselect word line. In one example, each near_unselwl may be applied with vpass1−delta1 (indicated by the dashed line in FIG. 7), which is lower than vpass1 (indicated by the solid line in FIG. 7) by delta1, in each setup phase of a setup-sense stage. For example, each near_unselwl may be first discharged from vpass1 (at the end of the pre-pulse stage or the previous sense phase) to vpass1−delta1 at the beginning of a setup phase, then kept at vpass1−delta1 for a while, and eventually charged from vpass1−delta1 back to vpass1 at the end of the setup phase to be ready for sensing in the subsequent sensing phase. In another example, each far_unselwl may be applied with vpass5−delta2 (indicated by the dashed line in FIG. 7), which is lower than vpass5 (indicated by the solid line in FIG. 7) by delta2, in each setup phase of a setup-sense stage. For example, each far_unselwl may be first discharged from vpass5 (at the end of the pre-pulse stage or the previous sense phase) to vpass5−delta2 at the beginning of a setup phase, then kept at vpass5−delta2 for a while, and eventually charged from vpass5−delta2 back to vpass5 at the end of the setup phase to be ready for sensing in the subsequent sensing phase. It is understood that delta1 and delta2 may be the same or different in different examples. It is also understood that the duration and/or ratio in which near_unselwl or far_unselwl is applied and kept at the reduced voltage level vpass1−delta1 or vpass5−delta2 in a setup phase may vary in different examples so long as it can be charged back to the desired pass voltage vpass1 or vpass5 at the end of the setup phase.

In some implementations, as shown in FIG. 7, different from the near unselect word lines near_unselwl and far unselect word lines far_unselwl, the adjacent unselect word lines wln+−1 is kept at the same pass voltage vpass3 during the entire setup-sense stage, i.e., does not change between the setup phase and the sense phase, to minimize the impact on sensing due to its close proximity to the select word line selwl.

Additionally or alternatively, the flexible unselect word line bias voltage control scheme disclosed herein can reduce the bias voltage applied to the unselected word lines (pass voltages) in the pre-pulse stage as well. Different from the read operation in FIG. 5 in which each unselect word line is charged to a respective pass voltage vpass in the pre-pulse stage (e.g., by the end of the pre-pulse stage), at least some of the unselect word lines, such as the near unselect word lines near_unselwl and far unselect word lines far_unselwl, can be charged to a bias voltage that is lower than the respective pass voltage. In some implementations, in the pre-pulse stage, word line driver 308 is configured to apply the bias voltage (first voltage) that is lower than the respective pass voltage (second voltage) to an unselect word line. In one example, each near_unselwl may be applied with vpass1−delta1 (indicated by the dashed line in FIG. 7), which is lower than vpass1 (indicated by the solid line in FIG. 7) by delta1, in the pre-pulse stage. For example, each near_unselwl may be discharged to and kept at vpass1−delta1. In this case, at the beginning of the setup phase of the first setup-sense stage, each near_unselwl may not need to be discharged since its bias voltage is at vpass1−delta1, as opposed to vpass1, at the end of the pre-pulse stage. In another example, each far_unselwl may be applied with vpass5−delta2 (indicated by the dashed line in FIG. 7), which is lower than vpass5 (indicated by the solid line in FIG. 7) by delta2, in the pre-pulse stage. For example, each far_unselwl may be discharged to and kept at vpass5−delta2. In this case, at the beginning of the setup phase of the first setup-sense stage, each far_unselwl may not need to be discharged since its bias voltage is at vpass5−delta2, as opposed to vpass5, at the end of the pre-pulse stage. It is understood that in some examples, the bias voltage to which near_unselwl or far_unselwl is applied in the pre-pulse stage may not be the same as the bias voltage thereof in the setup phase of each setup-sense stage even though the bias voltage may be still lower than the respective pass voltage in the sense phase of each setup-sense stage.

Similarly, in the pre-pulse stage, word line driver 308 can be configured to apply either the pass voltage (e.g., vpass1, indicated by the solid line in FIG. 7) or the reduced bias voltage (e.g., vpass1−delta1, indicated by the dashed line in FIG. 7) to the select word line selwl. In one example, selwl may be first charged to vpass by the end of the pre-pulse stage and then discharged from vpass1 to vrd1/vvfy1 in the setup phase of the first setup-sense stage. In another example, selwl may be first charged to vpass1−delta1 by the end of the pre-pulse stage and then discharged from vpass1−delta1 to vrd1/vvfy1 in the setup phase of the first setup-sense stage.

In some implementations, as shown in FIG. 7, different from the select word line selwl, near unselect word lines near_unselwl, and far unselect word lines far_unselwl, the adjacent unselect word lines wln+−1 is only charged to the target pass voltage vpass3, but not to a reduced bias voltage, to minimize the impact on sensing due to its close proximity to the select word line selwl.

Additionally or alternatively, the flexible unselect word line bias voltage control scheme disclosed herein can reduce the bias voltage applied to the unselected word lines (pass voltages) in the post-pulse stage as well. Different from the read operation in FIG. 5, in which unselect word lines are kept at their respective pass voltages at the beginning of the post-pulse stage and then discharged from their respective pass voltages vpass in the post-pulse stage, each unselect word line can be first discharged to a bias voltage that is lower than the respective pass voltage at the beginning of the post-pulse stage. In some implementations, in the post-pulse stage, word line driver 308 is configured to apply a bias voltage (third voltage) that is lower than the respective pass voltage (second voltage) to an unselect word line. In one example, each near_unselwl may be first discharged from vpass1 to vpass1−delta3 (indicated by the dashed line in FIG. 7), which is lower than vpass1 (indicated by the solid line in FIG. 7) by delta3, in the post-pulse stage. For example, each near_unselwl may be first discharged to vpass1−delta3 at the beginning of the post-pulse stage and then discharged from vpass1−delta3 to the supply voltage. In another example, each far_unselwl may be first discharged from vpass5 to vpass5−delta4 (indicated by the dashed line in FIG. 7), which is lower than vpass5 (indicated by the solid line in FIG. 7) by delta4, in the post-pulse stage. For example, each far_unselwl may be first discharged to vpass5−delta4 at the beginning of the post-pulse stage and then discharged from vpass5−delta4 to the supply voltage. In still another example, each wln+−1 may be first discharged from vpass3 to vpass1−delta3 (indicated by the dashed line in FIG. 7, the same bias voltage on near_unselwl), which is lower than vpass1 (indicated by the solid line in FIG. 7) by delta3, in the post-pulse stage. For example, each wln+−1 may be first discharged to vpass1−delta3 at the beginning of the post-pulse stage and then discharged from vpass1−delta3 to the supply voltage. It is understood that delta3 and delta4 may be the same or different in different examples. It is also understood that delta1 and delta3 may be the same or different in different examples. It is further understood that delta2 and delta4 may be the same or different in different examples. In one example, delta1, delta2, delta3, and delta4 are all the same.

Similarly, in the post-pulse stage, word line driver 308 can be configured to charge the select voltage line selwl to either the pass voltage (e.g., vpass1, indicated by the solid line in FIG. 7) or the reduced bias voltage (e.g., vpass1−delta3, indicated by the dashed line in FIG. 7). In one example, selwl may be first charged to vpass1 at the beginning of the post-pulse stage and then discharged from vpass1 to the supply voltage. In another example, selwl may be first charged to vpass1−delta3 at the beginning of the post-pulse stage and then discharged from vpass1−delta3 to the supply voltage.

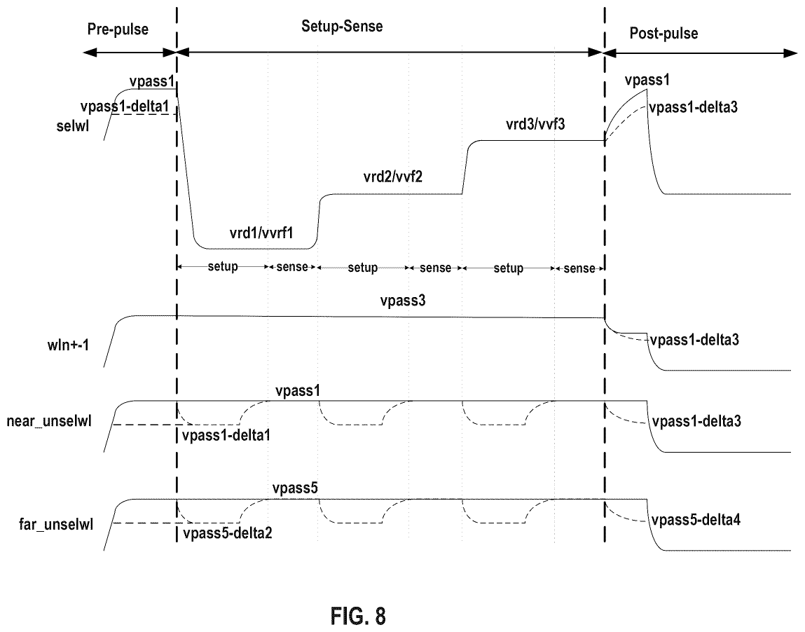

FIG. 8 illustrates another timing diagram of a read operation or a verify operation, according to some aspects of the present disclosure. The read operation in FIG. 8 is similar to the read operation described above with respect to FIG. 7 except that the read voltage vrd or the verify voltage vvrf applied to the select word line selwl in the setup-sense stages are increased, e.g., vrd1/vvrf1 is lower than vrd2/vvrf2, and vrd2/vvrf2 is lower than vrd3/vvrf3. The flexible unselect word line bias voltage control scheme disclosed herein can be similarly applied to both read operations described with respect to FIGS. 7 and 8, regardless of whether the read voltage vrd or the verify voltage vvrf is increasing or decreasing in the setup-sense stages.

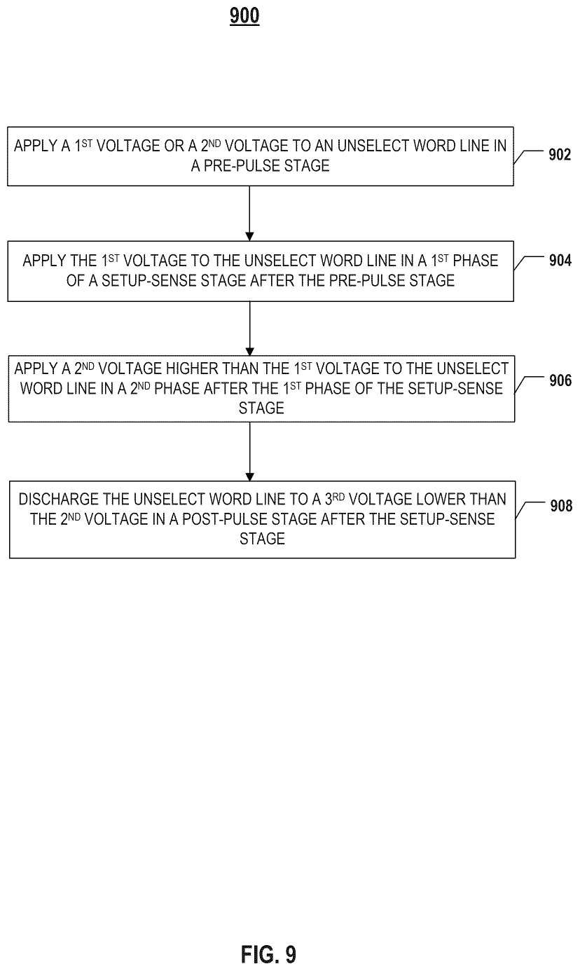

FIGS. 9 and 10 illustrate a flowchart of a method 900 for operating a memory device, according to some aspects of the present disclosure. The memory device may be any suitable memory device disclosed herein, such as memory device 100. Method 900 may be implemented by peripheral circuit 102, such as word line driver 308, page buffer 304, and control logic 312. It is understood that the operations shown in method 900 may not be exhaustive and that other operations can be performed as well before, after, or between any of the illustrated operations. Further, some of the operations may be performed simultaneously, or in a different order than shown in FIGS. 9 and 10. Method 900 in FIGS. 9 and 10 will be described with reference to the timing diagram of FIGS. 7 and 8. FIG. 9 refers to the operations of an unselect word line, and FIG. 10 refers to the operations of a select word line. The select word line may be coupled to a select row of memory cells, and the unselect word line may be coupled to an unselect row of the memory cells.

Referring to FIG. 9, method 900 starts at operation 902, in which a first voltage or a second voltage is applied to the unselect word line in a pre-pulse stage at 902. In some implementations, the unselect word line is not immediately adjacent to the select word line. In one example, in FIGS. 7 and 8, near_unselwl may be applied with a bias voltage vpass1−delta1 (indicated by the dashed line), and far_unselwl may be applied with another bias voltage vpass5−delta2 (indicated by the dashed line) in the pre-pulse stage. In another example, in FIGS. 7 and 8, near_unselwl may be applied with a pass voltage vpass1 (indicated by the solid line), and far_unselwl may be applied with another pass voltage vpass5 (indicated by the solid line) in the pre-pulse stage.

Method 900 proceeds to operation 904, as illustrated in FIG. 9, in which the first voltage is applied to the unselect word line in a first phase of a setup-sense stage after the pre-pulse stage. In some implementations, the unselect word line includes a first unselect word line and a second unselect word line that is farther away from the select word line than the first unselect word line, and the first voltage applied to the first unselect word line is different from the first voltage applied to the second unselect word line in the setup-sense stage. For example, in FIGS. 7 and 8, near_unselwl may be applied with the bias voltage vpass1−delta1 (indicated by the dashed line), and far_unselwl may be applied with the bias voltage vpass5−delta2 (indicated by the dashed line) in the setup phase of each setup-sense stage. In one example, vpass1−delta1 is different from vpass5−delta2.

Method 900 proceeds to operation 906, as illustrated in FIG. 9, in which a second voltage higher than the first voltage is applied to the unselect word line in a second phase after the first phase of the setup-sense stage. In some implementations, the second voltage is higher than the threshold voltages of the memory cells in the select row of memory cells. For example, in FIGS. 7 and 8, near_unselwl may be applied with a pass voltage vpass1 higher than the bias voltage vpass1−delta1 (indicated by the solid line), and far_unselwl may be applied with another pass voltage vpass5 higher than the bias voltage vpass5−delta2 (indicated by the solid line) in the sense phase of each setup-sense stage.

It is understood that in some examples, the second voltage may be applied to the unselect word line in the pre-pulse stage at 902. For example, in FIGS. 7 and 8, near_unselwl may be applied with the pass voltage vpass1 (indicated by the solid line), and far_unselwl may be applied with the pass voltage vpass5 (indicated by the solid line) in the pre-pulse stage.

It is also understood that in some examples, the same voltage is applied to another unselect word line in the first phase and the second phase of the setup-sense stage. The another unselect word line may be coupled to another unselect row of the rows of the memory cells and may be immediately adjacent to the select word line. For example, in FIGS. 7 and 8, win+−1 may be applied with the same pass voltage vpass3 in both the setup phase and the sense phase of each setup-sense stage.

Method 900 proceeds to operation 908, as illustrated in FIG. 9, in which the unselect word line is discharged to a third voltage lower than the second voltage in a post-pulse stage after the setup-sense stage. For example, in FIGS. 7 and 8, near_unselwl may be first discharged from the pass voltage vpass1 to another bias voltage vpass1−delta3 lower than the pass voltage vpass1 (indicated by the dashed line), and far_unselwl may be first discharged from the pass voltage vpass5 to another bias voltage vpass5−delta4 lower than the pass voltage vpass5 (indicated by the dashed line) in the post-pulse stage.

As to the operations of the select word line, referring to FIG. 10, method 900 starts at operation 1002, in which the first voltage or the second voltage is applied to the select word line in the pre-pulse stage. In one example, in FIGS. 7 and 8, selwl may be applied with the bias voltage vpass1−delta1 (indicated by the dashed line) in the pre-pulse stage. In another example, in FIGS. 7 and 8, selwl may be applied with the pass voltage vpass1 (indicated by the solid line) in the pre-pulse stage.

Method 900 proceeds to operation 1004, as illustrated in FIG. 10, in which a read voltage or a verify voltage is applied to the select word line in the setup-sense stage. In some implementations, the state of a memory cell in the select row is sensed in the second phase. For example, as shown in FIGS. 7 and 8, selwl may be applied with a read voltage vrd or a verify voltage vvrf in each setup-sense stage to sense the state of the select memory cell in the sense phase of each setup-sense stage.

Method 900 proceeds to operation 1006, as illustrated in FIG. 10, in which the select word line is charged to the third voltage in the post-pulse stage. For example, in FIGS. 7 and 8, selwl may be first charged to a bias voltage vpass1−delta3 (indicated by the dashed line) in the post-pulse stage. It is understood that in some examples, the select word line may be charged to the second voltage in the post-pulse at 1006. For example, in FIGS. 7 and 8, selwl may be first charged to the pass voltage vpass1 (indicated by the solid line) in the post-pulse stage.

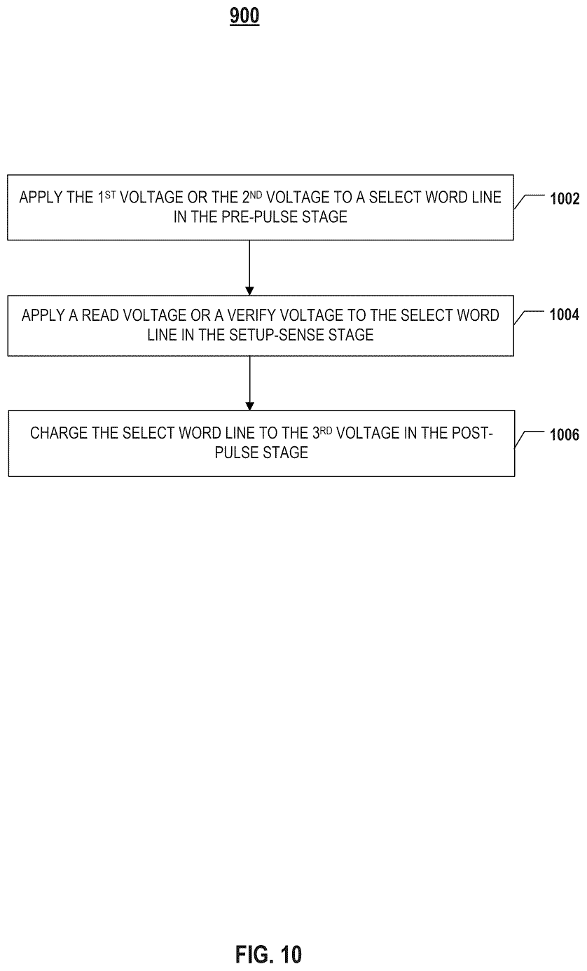

FIG. 11 illustrates a block diagram of a system 1100 having a memory device, according to some aspects of the present disclosure. System 1100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 11, system 1100 can include a host 1108 and a memory system 1102 having one or more memory devices 100 (shown in FIG. 1) and a memory controller 1106. Host 1108 can be a processor of an electronic device, such as a central processing unit (CPU), or a system-on-chip (SoC), such as an application processor (AP). Host 1108 can be configured to send or receive data to or from memory devices 100.

Memory device 100 can be any memory device disclosed in the present disclosure. Memory controller 1106 is coupled to memory device 100 and host 1108 and is configured to control memory device 100, according to some implementations. Memory controller 1106 can manage the data stored in memory device 100 and communicate with host 1108. In some implementations, memory controller 1106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1106 can be configured to control operations of memory device 100, such as read, erase, and program operations. Memory controller 1106 can also be configured to manage various functions with respect to the data stored or to be stored in memory device 100 including, but not limited to bad-block management, garbage collection, logical-to-physical address conversion, wear leveling, etc. In some implementations, memory controller 1106 is further configured to process error correction codes (ECCs) with respect to the data read from or written to memory device 100. Any other suitable functions may be performed by memory controller 1106 as well, for example, formatting memory device 100. Memory controller 1106 can communicate with an external device (e.g., host 1108) according to a particular communication protocol. For example, memory controller 1106 may communicate with the external device through at least one of various interface protocols, such as a USB protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

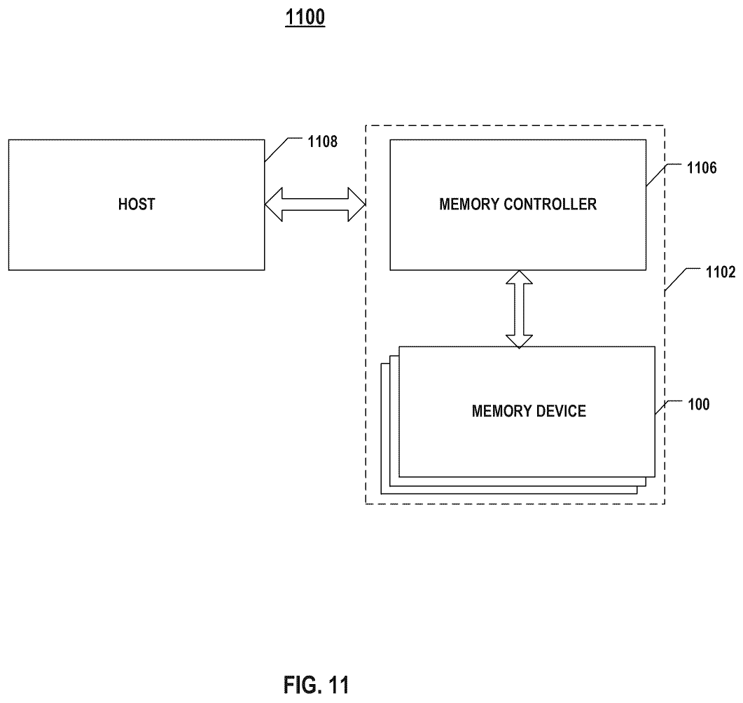

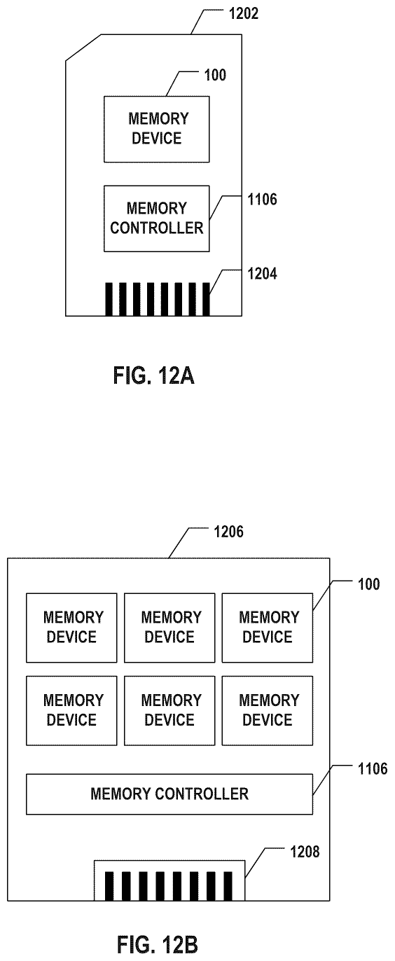

Memory controller 1106 and one or more memory devices 100 can be integrated into various types of storage devices, for example, being included in the same package, such as a universal Flash storage (UFS) package or an eMMC package. That is, memory system 1102 can be implemented and packaged into different types of end electronic products. In one example as shown in FIG. 12A, memory controller 1106 and a single memory device 100 may be integrated into a memory card 1202. Memory card 1202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1202 can further include a memory card connector 1204 coupling memory card 1202 with a host (e.g., host 1108 in FIG. 11). In another example as shown in FIG. 12B, memory controller 1106 and multiple memory devices 100 may be integrated into an SSD 1206. SSD 1206 can further include an SSD connector 1208 coupling SSD 1206 with a host (e.g., host 1108 in FIG. 11). In some implementations, the storage capacity and/or the operation speed of SSD 1206 is greater than those of memory card 1202.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A memory device, comprising:
an array of memory cells;
word lines respectively coupled to rows of the memory cells; and
a peripheral circuit coupled to the array of memory cells through the word lines and configured to read or verify a select row of the rows of the memory cells, wherein to read or verify the select row, the peripheral circuit is configured to:
apply a first voltage to an unselect word line coupled to an unselect row of the rows of the memory cells in a first phase of a first setup-sense stage; and
apply a second voltage higher than the first voltage to the unselect word line in a second phase after the first phase of the first setup-sense stage.

2. The memory device of claim 1, wherein the peripheral circuit is further configured to apply a first read voltage or a first verify voltage to a select word line coupled to the select row of the rows of the memory cells in the first setup-sense stage.

3. The memory device of claim 2, wherein the peripheral circuit is further configured to sense a state of a memory cell in the select row in the second phase.

4. The memory device of claim 2, wherein the peripheral circuit is further configured to:
apply the first voltage to the unselect word line in a pre-pulse stage before the first setup-sense stage; and
apply the first voltage to the select word line in the pre-pulse stage.

5. The memory device of claim 2, wherein the peripheral circuit is further configured to:
apply the second voltage to the unselect word line in a pre-pulse stage before the first setup-sense stage; and
apply the second voltage to the select word line in the pre-pulse stage.

6. The memory device of claim 2, wherein the peripheral circuit is further configured to discharge the unselect word line to a third voltage lower than the second voltage in a post-pulse stage after the first setup-sense stage.

7. The memory device of claim 6, wherein the peripheral circuit is further configured to charge the select word line to the third voltage in the post-pulse stage.

8. The memory device of claim 1, wherein the peripheral circuit is further configured to:
apply a second read voltage or a second verify voltage to the select word line in a second setup-sense stage;
apply the first voltage to the unselect word line in a first phase of the second setup-sense stage; and
apply the second voltage to the unselect word line in a second phase after the first phase of the second setup-sense stage.

9. The memory device of claim 1, wherein the second voltage is higher than threshold voltages of the memory cells in the select row.

10. The memory device of claim 1, wherein the unselect word line is not immediately adjacent to the select word line.

11. The memory device of claim 10, wherein the peripheral circuit is further configured to apply a same voltage to another unselect word line coupled to another unselect row of the rows of the memory cells in the first phase and the second phase of the first setup-sense stage, the another unselect word line being immediately adjacent to the select word line.

12. The memory device of claim 10, wherein
the unselect word line comprises a first unselect word line and a second unselect word line;
the second unselect word line is farther away from the select word line than the first unselect word line; and
the first voltage applied to the first unselect word line is different from the first voltage applied to the second unselect word line in the first setup-sense stage.

13. A method for operating a memory device, the memory device comprising an array of memory cells and word lines respectively coupled to rows of the memory cells, the method comprising:
applying a first read voltage or a first verify voltage to a select word line of the word lines in a first setup-sense stage, the select word line being coupled to a select row of the rows of the memory cells;
applying a first voltage to an unselect word line of the word lines in a first phase of the first setup-sense stage, the unselect word line being coupled to an unselect row of the rows of the memory cells; and
applying a second voltage higher than the first voltage to the unselect word line in a second phase after the first phase of the first setup-sense stage.

14. The method of claim 13, further comprising sensing a state of a memory cell in the select row in the second phase.

15. The method of claim 13, further comprising:
applying the first voltage to the unselect word line in a pre-pulse stage before the first setup-sense stage; and
applying the first voltage to the select word line in the pre-pulse stage.

16. The method of claim 13, further comprising:
applying the second voltage to the unselect word line in a pre-pulse stage before the first setup-sense stage; and
applying the second voltage to the select word line in the pre-pulse stage.

17. The method of claim 13, further comprising discharging the unselect word line to a third voltage lower than the second voltage in a post-pulse stage after the first setup-sense stage.

18. The method of claim 17, further comprising charging the select word line to the third voltage in the post-pulse stage.

19. The method of claim 13, further comprising:
applying a second read voltage or a second verify voltage to the select word line in a second setup-sense stage;
applying the first voltage to the unselect word line in a first phase of the second setup-sense stage; and
applying the second voltage to the unselect word line in a second phase after the first phase of the second setup-sense stage.

20. A system, comprising:
a memory device configured to store data, the memory device comprising:
an array of memory cells;
word lines respectively coupled to rows of the memory cells; and
a peripheral circuit coupled to the array of memory cells through the word lines and configured to read or verify a select row of the rows of the memory cells, wherein to read or verify the select row, the peripheral circuit is configured to:
apply a first voltage to an unselect word line coupled to an unselect row of the rows of the memory cells in a first phase of a first setup-sense stage; and
apply a second voltage higher than the first voltage to the unselect word line in a second phase after the first phase of the first setup-sense stage; and
a memory controller coupled to the memory device and configured to control the memory device.
